(19) United States
(12) Patent Application Publication
(10) Pub. No.: US 2006/0137901 A1
(43) Pub. Date: Jun. 29, 2006

(54) Electronic device including a substrate structure and a process for forming the same

(76) Inventors: Gang Yu, Santa Barbara, CA (US); Runguang Sun, Shanghai (CN)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/025,127

(22) Filed: Dec. 29, 2004

(51) Int. Cl. H05K 1/00; H05K 3/36

(52) U.S. Cl. 174/250; 29/831; 29/830; 156/314

(57) ABSTRACT

An electronic device includes a first substrate including a first exposed conductor and a second exposed conductor. The electronic device also includes a second substrate and a conductive material that includes a first portion that contacts the first exposed conductor and a second portion that contacts the second exposed conductor. The electronic device further includes a first substrate structure that electrically insulates the first portion of the conductive material from the second portion of the conductive material. A process for forming an electronic device includes depositing a liquid adhesive over a first substrate. The process further includes contacting the liquid adhesive with a second substrate near a first edge of the second substrate. The process still further includes increasing the contact area between the liquid adhesive and second substrate as the second edge of the second substrate is moved closer to the first substrate.

### BACKGROUND OF THE INVENTION

1. Field of the Invention

The invention relates generally to electronic devices and processes for forming the same, and more specifically, to electronic devices including substrate structures and processes for forming the same.

2. Description of the Related Art

Electronic devices, including organic electronic devices, continue to be more extensively used in everyday life. Examples of organic electronic devices include Organic Light-Emitting Diodes (“OLEDs”). Conventional OLED displays are typically formed from a single substrate. Whether passive matrix or active matrix, electronic circuits used to drive the OLEDs are formed before the OLEDs, themselves. Electronic circuits that are otherwise good may become effectively worthless during the fabrication of the OLEDs. For example, a fabrication defect or error when forming the OLEDs can result in operable driver circuits that are connected to non-functional or poorly functioning OLEDs. In another example, fabrication of the OLEDs may render the driver circuits to be non-functional or poorly functioning due to processing conditions. Such non-functional or poorly functioning driver circuits may result from temperature cycling, plasma damage, or the like. Still further, the additional processing for the OLEDs increases the likelihood that a substrate will be dropped, fractured, misplaced, or combined with the wrong lot of substrates.

In an attempt to solve the problem, one substrate includes electronic circuits, and another substrate includes the OLEDs. The exposed conductors on each of the substrates may be electrically connected to one another using discrete conductive members. A single discrete conductive member, or at least one discrete conductive member of a plurality of discrete conductive members, contacts exposed conductors on each of the substrates. When a plurality of discrete conductive members are used, the density of discrete conductive members is relatively low to prevent electrical shorting or the formation of a leakage path between exposed conductors that are not to be connected. The single discrete conductive member, or plurality of discrete conductive members, may not have the ability to support the current density required to operate an array of OLEDs, particularly those arrays that are used in outdoor displays or in lighting panels.

### SUMMARY OF THE INVENTION

An electronic device includes a first substrate including a first exposed conductor and a second exposed conductor. The electronic device also includes a second substrate and a conductive material that includes a first portion that contacts the first exposed conductor and a second portion that contacts the second exposed conductor. The electronic device further includes a first substrate structure that electrically insulates the first portion of the conductive material and the first exposed conductor from the second portion of the conductive material and the second exposed conductor.

A process for forming an electronic device includes depositing a liquid adhesive over a first substrate. The process also includes placing the first substrate and a second substrate under vacuum. The second substrate has a first edge and a second edge opposite the first edge. The process further includes contacting the liquid adhesive with the second substrate near the first edge of the second substrate. The process still further includes increasing the contact area between the liquid adhesive and second substrate as the second edge of the second substrate is moved closer to the first substrate. The process yet further includes curing the liquid adhesive.

The foregoing general description and the following detailed description are exemplary and explanatory only and are not restrictive of the invention, as defined in the appended claims.

### BRIEF DESCRIPTION OF THE FIGURES

The invention is illustrated by way of example and not limitation in the accompanying figures, in which the same reference number indicates similar elements in the different figures.

FIG. 1 includes an illustration of a cross-sectional view of a portion of a substrate that includes pixel driver circuits and exposed conductors.

FIG. 2 includes an illustration of a cross-sectional view of a portion of a substrate that includes a first electrode, substrate structures, an organic layer, and exposed electrodes.

FIG. 3 includes an illustration of a cross-sectional view of the substrate of FIG. 2 after forming a liquid adhesive including discrete conductive members over the exposed conductors.

FIG. 4 includes an illustration of a cross-sectional view of the substrates of FIGS. 2 and 3 during a joining operation.

FIG. 5 includes an illustration of a cross-sectional view of the substrate of FIG. 4 after forming a substantially completed electronic device.

FIGS. 6 to 8 include illustrations of cross-sectional views of portions of substrates having different sizes or densities of discrete conductive members in accordance with alternative embodiments.

FIGS. 9 to 13 include illustrations of cross-sectional views of portions of substrates having different substrate structures in accordance with alternative embodiments.

FIGS. 14 to 17 include illustrations of cross-sectional views of portions of a substrate and a lid used in an encapsulation process in accordance with an alternative embodiment.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

An electronic device includes a first substrate including a first exposed conductor and a second exposed conductor. The electronic device also includes a second substrate and a conductive material that includes a first portion that contacts the first exposed conductor and a second portion that contacts the second exposed conductor. The electronic device further includes a first substrate structure that electrically insulates the first portion of the conductive material and the first exposed conductor from the second portion of the conductive material and the second exposed conductor.

In another embodiment, from a cross-sectional view, the first substrate structure has an apex that has a point, is rounded, is flat, or a combination thereof.

In still another embodiment, the electronic device further includes a third exposed conductor. The second substrate includes the third exposed conductor. The first portion of the conductive material is connected to the first and third exposed conductors. In a specific embodiment, discrete conductive members include the conductive material, and the discrete conductive members include a first discrete conductive member and a second discrete conductive member. In a more specific embodiment, the first discrete conductive member contacts the first exposed conductor but not the third exposed conductor. The second discrete conductive member contacts the third exposed conductor but not the first exposed conductor. In another more specific embodiment, the discrete conductive members include a third discrete conductive member that electrically floats. In a further more specific embodiment, the electronic device further includes a second substrate structure, wherein the third discrete conductive member lies within a valley between the first and second substrate structures.

In another specific embodiment, the discrete conductive members including a conductive organic material, conductive metallic-coated elastic balls, or a combination thereof. In a still another specific embodiment, the conductive material is capable of supporting a current density of at least 1 mA/cm² between the first and third exposed conductors.

In yet another embodiment, he electronic device further includes a second substrate structure. The first substrate includes the first substrate structure, and the second substrate includes the second substrate structure. The first substrate structure and second substrate structure are corresponding structures that can be used for aligning the first and second substrates to each other.

A process for forming an electronic device includes depositing a liquid adhesive over a first substrate. The process also includes placing the first substrate and a second substrate under vacuum. The second substrate has a first edge and a second edge opposite the first edge. The process further includes contacting the liquid adhesive with the second substrate near the first edge of the second substrate. The process still further includes increasing the contact area between the liquid adhesive and second substrate as the second edge of the second substrate is moved closer to the first substrate. The process yet further includes curing the liquid adhesive.

In another embodiment, the liquid adhesive has a viscosity no greater than 20 centipoise during increasing the contact area. In a specific embodiment, curing includes exposing the liquid adhesive to radiation or heat, allowing the liquid adhesive to set, or a combination thereof. In a more specific embodiment, increasing the contact area is performed using an inert ambient. In another specific embodiment, the process is performed such that substantially no bubbles are formed between the liquid adhesive and the second substrate.

In still another embodiment, the process further includes forming a substrate structure on the first substrate, forming a first exposed conductor and a second exposed conductor on the first substrate, and forming a third exposed conductor and a fourth exposed conductor on the second substrate. In a specific embodiment, depositing the liquid adhesive includes depositing a first portion of the conductive material over the first exposed conductor and depositing a second portion of the conductive material over the second exposed conductor. The substrate structure lies between the first and second portions of the conductive material. In a more specific embodiment, increasing the contact area including contacting the first portion of the conductive material with the third exposed conductor and contacting the second portion of the conductive material with the fourth exposed conductor. The substrate structure electrically insulates the first and third exposed conductors from the second and fourth exposed conductors.

In a further more specific embodiment, forming the first exposed conductor includes forming a fifth exposed conductor over the substrate structure. The process further includes removing the fifth exposed conductor before depositing the liquid adhesive. In yet another embodiment, an electronic device is formed by the process.

Other features and advantages of the invention will be apparent from the following detailed description, and from the claims. The detailed description first addresses Definitions and Clarification of Terms followed by Electronic Circuits and Electronic Components on Different Substrates, Alternative Discrete Conductive Members, Alternative Substrate Structures, Alternative Process for Joining Substrates, and finally Advantages.

1. Definitions and Clarification of Terms

Before addressing details of embodiments described below, some terms are defined or clarified. The terms “apex,” when referring to a substrate structure is intended to mean a point of the substrate structure having the farthest distance from the substrate. A substrate structure can have more than one apex.

The terms “array,” “peripheral circuitry” and “remote circuitry” are intended to mean different areas or components of the organic electronic device. For example, an array may include pixels, cells, or other structures within an orderly arrangement (usually designated by columns and rows). The pixels, cells, or other structures within the array may be controlled locally by peripheral circuitry, which may lie within the same organic electronic device as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “conductive,” when referring to a material, is intended to mean a material that allows a significant current to flow through the material. In one embodiment, a conductive material has a bulk resistivity no greater than approximately 10⁺⁶ ohm-cm.

The term “connected,” with respect to electronic components, circuits, or portions thereof, is intended to mean that two or more electronic components, circuits, or any combination of at least one electronic component and at least one circuit do not have any intervening electronic component lying between them. Parasitic resistance, parasitic capacitance, or both are not considered electronic components for the purposes of this definition. In one embodiment, electronic components are connected when they are electrically shorted to one another and lie at substantially the same voltage. Note that electronic components can be connected together using fiber optic lines to allow optical signals to be transmitted between such electronic components.

The term “cure” is intended to mean a process under which a layer, member, or structure undergoes an irreversible change without an introduction of any additional material into such layer, member, or structure during the process.

The term “discrete conductive member” is intended to mean a patterned layer, member, or structure that forms a conductive unit that is separate and distinct from a different discrete conductive member. For example, metallic particles within an epoxy are discrete conductive members.

The term “electrically float” or “float” is intended to mean that at least a portion of one or more component, circuit, or any combination thereof is not electrically connected to any other one or more component, circuit, or any combination thereof or a power supply, or is part of an electrically open circuit.

The term “electrically insulates” is intended to mean that a material, layer, member, or structure has an electrical property such that it substantially prevents a significant number of charge carriers from flowing through such material, layer, member or structure.

The term “electronic component” is intended to mean a lowest level unit of a circuit that performs an electrical or electro-radiative (e.g., electro-optic) function. An electronic component may include a transistor, a diode, a resistor, a capacitor, an inductor, a semiconductor laser, an optical switch, or the like. An electronic component does not include parasitic resistance (e.g., resistance of a wire) or parasitic capacitance (e.g., capacitive coupling between two conductors connected to different electronic components where a capacitor between the conductors is unintended or incidental).

The term “electronic device” is intended to mean a collection of circuits, electronic components, or combinations thereof that collectively, when properly connected and supplied with the appropriate potential(s), performs a function. An electronic device may include or be part of a system. An example of an electronic device includes a display, a sensor array, a computer system, an avionics system, an automobile, a cellular phone, or other consumer or industrial electronic product.

The term “exposed conductor,” when referring to a substrate at a particular point in time, is intended to mean a conductor that can be in contact with an object, an ambient, or a combination thereof outside of or separate from the substrate.

The term “inert ambient” is intended to mean an ambient that does not significantly react with a layer, material, member, structure, or any combination thereof to which such ambient is exposed.

The term “liquid adhesive” is intended to mean a substance that at a particular point in time (e.g., during application or other deposition) is a liquid, wherein the substance, that while a liquid or after a processing act or time (e.g., curing or allowing to set), adheres to a surface of an object.

The term “metallic” is intended to mean containing one or more metals. For example, a metallic coating can include an elemental metal by itself, a clad, an alloy, a plurality of layers of any combination of an elemental metal, a clad, or an alloy, or any combination of the foregoing.

The term “organic active layer” is intended to mean one or more organic layers, wherein at least one of the organic layers, by itself, or when in contact with a dissimilar material is capable of forming a rectifying junction.

The term “precision deposition technique” is intended to mean a deposition technique that is capable of depositing one or more materials over a substrate to a thickness no greater than approximately one millimeter. A stencil mask, frame, well structure, patterned layer or other structure(s) may be present during such deposition.

The term “radiation-emitting component” is intended to mean an electronic component, which when properly biased, emits radiation at a targeted wavelength or spectrum of wavelengths. The radiation may be within the visible-light spectrum or outside the visible-light spectrum (ultraviolet (“UV”) or infrared (“IR”)). A light-emitting diode is an example of a radiation-emitting component.

The term “radiation-responsive component” is intended to mean an electronic component can sense or respond to radiation at a targeted wavelength or spectrum of wavelengths. The radiation may be within the visible-light spectrum or outside the visible-light spectrum (UV or IR). Photodetectors, IR sensors, biosensors, and photovoltaic cells are examples of radiation-responsive components.

The term “rectifying junction” is intended to mean a junction within a semiconductor layer or a junction formed by an interface between a semiconductor layer and a dissimilar material in which charge carriers of one type flow easier in one direction through the junction compared to the opposite direction. A pn junction is an example of a rectifying junction that can be used as a diode.

The term “substrate” is intended to mean a workpiece, including at least one electronic component, at least one conductor to connect electronic components or an electronic component to a power supply line, that can be either rigid or flexible and may be include one or more layers of one or more materials, which can include, but are not limited to, glass, polymer, metal or ceramic materials or combinations thereof. In one embodiment, a lid can be a substrate.

The term “substrate structure” is intended to mean one or more members, patterned layers, or a combination of member(s) and layer(s) overlying a substrate.

The term “valley” is intended to mean a low point or depression. A layer, member, or structure can have more than one valley, and if more than one valley is present, the lowest elevations of the valleys may be the same or different compared to each other.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, for clarity purposes and to give a general sense of the scope of the embodiments described herein, the use of the “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Group numbers corresponding to columns within the periodic table of the elements use the “New Notation” convention as seen in the CRC Handbook of Chemistry and Physics, 81^{st} Edition (2000).

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductor arts.

2. Electronic Circuits and Electronic Components on Different Substrates

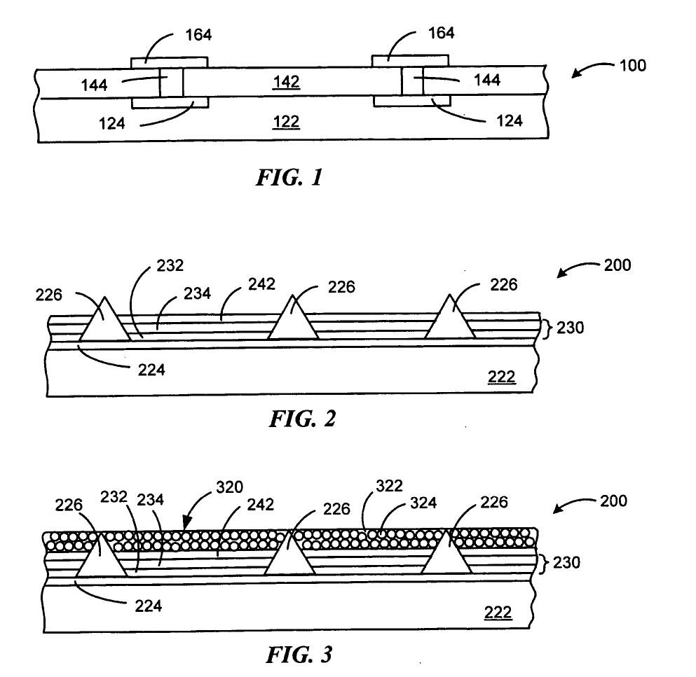

Attention is now directed to details in an exemplary embodiment that is described and illustrated in FIGS. 1 to 5. Referring to FIG. 1, a substrate 100 includes a base material 122 and pixel driver circuits 124. The base material 122 may include one or more materials conventionally used in the organic electronic device arts. Pixel driver circuits 124 and other circuits (not illustrated) may be formed within or over the base material 122 using conventional techniques. The other circuits (not illustrated) outside the array may include peripheral and remote circuitry used to control the pixels within the array. The focus of fabrication is on the array rather than the peripheral or remote circuitry.

Insulating layer 142, which contains conductive plugs 144, is then formed using one or more of any number of conventional techniques such that each conductive plug 144 is electrically connected to a pixel driver circuit 124. In one embodiment, the insulating layer 142 is deposited as one or more patterned layer(s) using a stencil mask. In another embodiment, the insulating layer 142 is blanket deposited and patterned using a conventional lithographic technique to form openings to the pixel driving circuits 124. In one embodiment, the conductive plugs 144 are formed using a selective deposition or blanket depositing one or more layers and polishing, etching, or otherwise removing portions of such layer(s) lying outside of the openings within the insulating layer 142.

Exposed conductors 164 are then formed using one or more of any number of conventional techniques, and each exposed conductor 164 electrically contacts one of the conductive plugs 144. In one embodiment, the exposed conductors 164 are deposited as one or more patterned layers using a stencil mask. In another embodiment, the exposed conductors are formed by blanket depositing one or more layers and patterning such layer(s) using a conventional lithographic technique.

The exposed conductors 164 are exposed to processing conditions when the substrate 100 is subsequently joined to a different substrate. In one embodiment, the exposed conductors 164 are compatible (i.e., no adverse interactions) with a conductive material, optional adhesive, substrate structures, and exposed conductors of another substrate as described in more detail later in this specification. The exposed conductors 164 can include at least one element selected from Groups 4 to 6, 8 and 10 to 14 of the Periodic Table, or any combination thereof. In one embodiment, the exposed conductors 164 can include Cu, Al, Ag, Au, Mo, or any combination thereof. In another embodiment, where the exposed conductors 164 include one layer, one of the layers can include Cu, Al, Ag, Au, Mo, or any combination thereof and another layer can include Mo, Cr, Ti, Ru, Ta, W, Si, or any combination thereof. Note that conductive metal oxide(s), conductive metal nitride(s) or a combination thereof may be used in place of or in conjunction with any of the elemental metals or alloys thereof. In another embodiment exposed conductors 164 have a thickness in a range of approximately 0.1 to 5 microns.

FIG. 2 illustrates a substrate 200 that comprises a base material 222, a first electrode 224, which serves as a common anode for the array, substrate structures 226, and organic layer 230, including an optional charge-transport layer 232 and an organic active layer 234, and exposed conductors 242, which are second electrodes or cathodes in one embodiment, all formed by conventional techniques. Each of the layer(s) within the first electrode 224, substrate structures 226, organic layer 230, and exposed conductors 242 are deposited and may or may not need to be patterned. In one embodiment, base material 222 and the first electrode 224 are substantially transparent to the targeted radiation wavelength or spectrum (spectra) of wavelengths to which the electronic device emits or responds. In another embodiment, more, fewer, or different layer(s) or feature(s) are present. For example, the organic layer 230 may include a charge-injection layer, a charge-blocking layer, or both in place of or in conjunction with the charge-transport layer 232. In still another embodiment, any one or more of different charge-injection, charge-transport, or charge-blocking layers may lie between the organic active layer 234 and the exposed conductors 242.

In one embodiment, the substrate structures 226 are used as well structures to divide the array into regions or areas corresponding to pixels or sub-pixels. The substrate structures 226 can include one or more electrically insulating materials. In one embodiment, the substrate structures 226 are compatible (i.e., no adverse interactions) with a subsequently deposited conductive material, optional adhesive, exposed conductors 164, and insulating layer 142. In one embodiment, the substrate structures 226 can include one or more inorganic materials (e.g., silicon dioxide, silicon nitride, aluminum oxide, aluminum nitride, etc.), one or more organic materials (e.g., photoresist, polyimide, polysiloxane, etc.), or any combination thereof. In one embodiment, the substrate structures 226 can include a black material (e.g., carbon) to help improve the contrast when the electronic device is used in ambient light conditions.

The substrate structures 226 can have different shapes. In one embodiment, as shown in FIG. 2, the substrate structures 226 have widths that are widest nearest the base material 222. In another embodiment (not illustrated), the substrate structures 226 have widths wider at a location further from the base material 222. The apexes of the substrate structures 226, which are the point or points farthest from the base material 222, may be pointed, rounded, flat, or a combination thereof. Although not meant to limit, in one embodiment, each of the substrate structures 226 has a width in a range of approximately 5 to 10 microns and a height in a range of approximately 2 to 5 microns. In one specific embodiment, all heights of the substrate structures 226 are substantially the same. In still another embodiment, the substrate substructures 226 can be replaced by a single substrate structure that has portions connected at locations that would not be seen in FIG. 2.

In one embodiment, the exposed conductors 242 are the cathodes for the electronic components being formed. The exposed conductors 242 include a first layer in contact with the organic layer 230 and a second layer overlying the first layer. The first layer includes one or more of a Group 1 metal, a Group 2 metal, or other materials conventionally used for cathodes within OLEDs. The second layer helps to protect the first layer. In one embodiment, the exposed conductors 242 are compatible (i.e., no adverse interactions) with subsequently deposited conductive material, optional adhesive, exposed conductors 164, and insulating layer 142. The second layer can include any one or more of the materials described with respect to the exposed conductors 164. The second layer of the exposed conductors 242 and the exposed conductors 164 can have the same material or different materials. In one embodiment, the exposed conductors 242 have a thickness in a range of approximately 0.1 to 5 microns.

In one embodiment, when the substrates 100 and 200 are joined, the pixel driver circuit 124 and the exposed conductor 164, previously illustrated in FIG. 1, may cover substantially all the area of exposed conductor 242. In another embodiment, the pixel driver circuit 124, the exposed conductor 164, or both may be formed substantially smaller in area than the exposed conductor 242.

FIG. 3 illustrates substrate 200 after applying or otherwise depositing of a bonding layer 320 comprising an adhesive 322 and discrete conductive members 324. The bonding layer 320 substantially fills the volume between the apexes of substrate structures 226 and above the exposed electrodes 242. In one embodiment, the bonding layer 320 has a thickness in a range of approximately 0.5 to 3 microns.

In one embodiment, the adhesive 322 can be a liquid adhesive having a viscosity no greater than 20 centipoise. While a higher viscosity may be used, bubbles or voids are more likely to form between the bonding layer 320 and the substrate 100 as the viscosity of the liquid adhesive increases. The adhesive 322 may be cured by radiation, elevated temperature, allowing it to set, or the like. In one embodiment, the adhesive 322 is cured with UV radiation to set more quickly the adhesive 322. The adhesive 322 can include an epoxy resin, a polyester, a polycarboxylic acid, a polyether, a polyurethane, a polyamide, a polyimide, a polybenzimidazole, a polyvinyl butyral, a poly(butyl methacrylate), a polyvinyl alcohol, a poly(acrylic acid), a poly(methyl vinyl ether/maleic anhydride), a styrene/butadiene copolymer, an acrylic/styrene copolymer, or any combination thereof.

The discrete conductive members 324 comprise one or more conductive materials including Al, Ag, Ni, Cr, Cu, Pt, In, Sn, Bi, Pb, Hg, Ga, Cd, an alloy thereof, or any combination thereof. As an alternative embodiment, the discrete conductive members 324 include metal-coated, elastic, plastic shells, and in another embodiment, the discrete conductive members 324 include an organic material. For example, a sulfonated version of polyaniline (“PANI-PSS”) or poly(3,4-ethylenedioxythiophene) (“PEDOT-PSS”) can be used as a conductive material. The PANI-PSS, PEDOT-PSS, or a combination thereof can be coated over relatively non-conductive plastic balls.

The discrete conductive members 324 can have nearly any shape including spherical, cylindrical, rectilinear, pyramid, ring, coil, tetrahedral, hourglass, any of the shapes used for packings in packed columns, or a combination thereof. In one embodiment, the size of each discrete conductive member 324 is in a range of approximately 0.1 to 5 microns. Each of the discrete conductive members 324 can have substantially the same or different sizes compared to one another.

In one embodiment, the bonding layer 320 is at least 17 volume percent of the discrete conductive members 324. Note that even when the bonding layer 320 includes at least 17 volume percent of the discrete conductive members 324, the bonding layer 320 may or may not be conductive as applied. In one embodiment, a bonding layer 320 may become conductive only after it is cured.

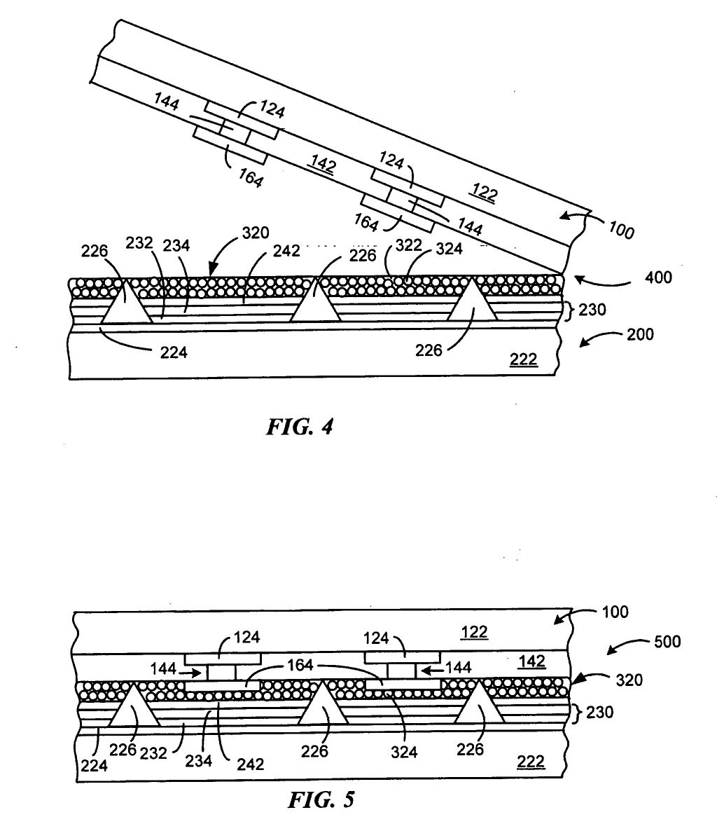

The substrates 100 and 200 can be joined as illustrated in FIG. 4. In order to reduce the likelihood that bubbles will form and become trapped, in one embodiment, the joining of the substrates 100 and 200 is performed under vacuum (i.e., lower than atmospheric pressure). In one embodiment, the pressure is not so low as to cause boiling or bubbles to form within the adhesive 322. Therefore, the lower limit of the pressure may be determined by the material(s) within the adhesive 322. In another embodiment, the pressure is in a range of approximately 0.1 mTorr to 10 Torr. In one embodiment, the joining may be performed at least partially or completely within an inert ambient (e.g., N₂, CO₂, a noble gas, or any combination thereof).

FIG. 4 illustrates the beginning of the attachment of the substrate 100 and the substrate 200 using the bonding layer 320. The substrate 100 is oriented so that the side with exposed conductor 164 is facing the bonding layer 320 on the substrate 200. The substrate 100 is placed in contact with the bonding layer 320 at an initial contact point 400. When the substrate 200 is curvable under gravity, the contact point 400 can be at the center (when all edges of the substrate 200 are held at the same elevation from the substrate 200), or at other locations within the substrate 200 determined by gravity and the relative holding level of each edge. The alignment between substrates 100 and 200 can be achieved with conventional alignment techniques known in the microelectronics industry. Contact progresses from the initial contact point 400 in a direction away from the initial contact point 400 to substantial completion as illustrated in FIG. 5. By joining the substrates 100 and 200 together in this manner, both gas(es) and excess bonding layer 320, if any, are forced from between the substrates 100 and 200, such that the substrate 100 is substantially in physical contact with the substrate 200 at the apexes of the substrate structures 226 with a reduced likelihood of bubbles or voids forming. If the substrate 100 was oriented substantially parallel to the substrate 200 during joining, bubbles or voids between the bonding layer 320 and the substrate 100 are significantly more likely to form. In one embodiment, the initial contact 400 between the substrates 100 and 200 may occur at a single point or as a line of points.

After the substrates 100 and 200 have been aligned and joined, the bonding layer 320 is cured to form a substantially completed electronic device 500 as illustrated in FIG. 5. Curing can be performed by exposure to radiation, heat, allowing the adhesive 322 to set (e.g., mere passage of time) or the like. The curing depends on the type of adhesive 322 is used; however, such curing is conventional. In one embodiment, the bonding layer 320 is cured by exposing the adhesive 322 to UV radiation. In another embodiment, the bonding layer 320 is cured by elevating the substrate temperature. In yet another embodiment, a combination of both is used (UV curing while at an elevated temperature).

In the electronic device 500, the region between the exposed conductor 164 and the exposed conductor 242 is filled by the bonding layer 320 such that a connection between the exposed conductors 164 and 242 is made via the discrete conductive members 324. In one embodiment, the connection between the exposed conductors 164 and 242 can support a current density of at least 1 mA/cm². In another embodiment, the current density is at least 11 mA/cm², and in still another embodiment, the current density is at least 101 mA/cm².

3. Alternative Discrete Conductive Members and Concentrations

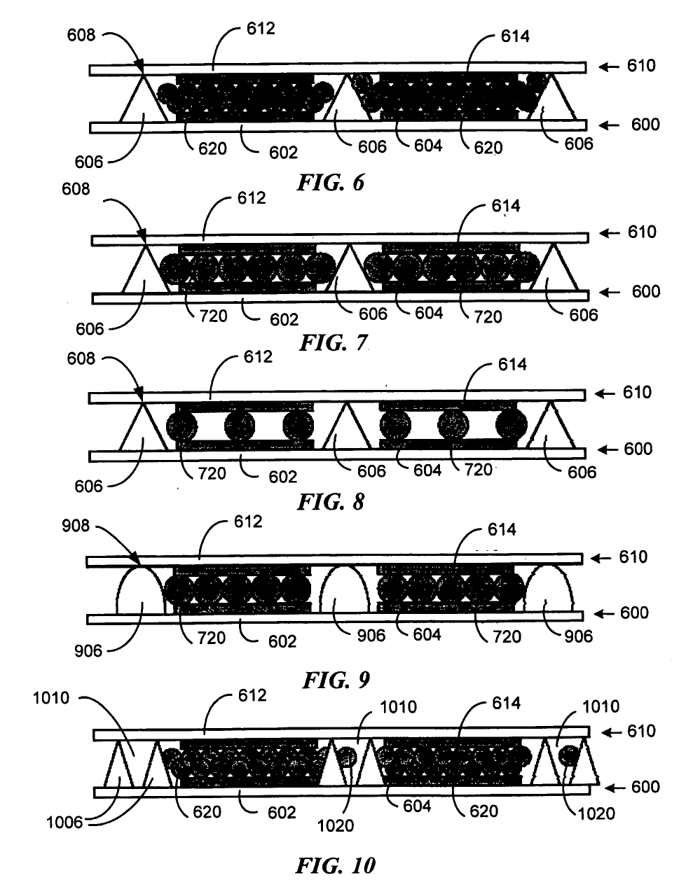

FIGS. 6 to 8 illustrate alternative embodiments using discrete conductive members. The discrete conductive members can include any of the materials previously described for discrete conductive members 324. FIG. 6 illustrates an embodiment including a first substrate 600 joined to a second substrate 610. The first substrate 600 comprises a base material 602, exposed conductors 604, and substrate structures 606 having apexes 608. The second substrate 610 comprises a base material 612 and exposed conductors 614. The base materials 602 and 612 may be the same or different, and the exposed conductors 604 and 614 may be the same or different. In one embodiment, one or both of the base materials 602 or 612 may include one or more electronic components, circuits, or electronic features (e.g., conductors) that are not illustrated in FIG. 6. Discrete conductive members 620 connect the exposed conductors 604 and 614 to each other. In one embodiment, the size of discrete conductive members 620 is selected such that the region between the exposed conductors 604 and 614 is not bridged by a single discrete conductive member 620. Some of the discrete conductive members contact exposed conductors 602, other discrete conductive members contact exposed conductor 614. In one embodiment, still other discrete conductive members 620 do not contact any of the exposed conductors 602 or 604.

In another embodiment as illustrated in FIG. 7 each discrete conductive member 720 is large enough to bridge the region between the exposed conductors 604 and 614. In still another embodiment, the concentration of the discrete conductive members 720 can be varied. FIG. 8 includes an illustration where the concentration of the discrete conductive members 720 is lower compared to the embodiment illustrated in FIG. 7. In another embodiment (not illustrated), the concentration of the discrete conductive members 720 is higher. The substrate structures 606 are electrically insulated and may substantially prevent the formation of an unintended conducting or leakage path. Therefore, undesired connections between exposed conductors 602, between exposed conductors 604, or a combination thereof can be prevented even if the size, the concentration or both of the discrete conductors change.

In another embodiment (not illustrated) the conduction paths in regions between substrate structures 606 is formed by discrete conductive members having different sizes, such as the discrete conductive members 620 and 720. In still another embodiment (not illustrated), the discrete conductive members 620, 720, or a combination thereof have a different shape. Nearly any shape is possible, and a list of a few examples of shapes is previously described.

Additionally, the discrete conductive members 620, 720, or a combination thereof may or may not be part of a bonding layer. If the discrete conductive members 620, 720, or a combination thereof are part of a bonding layer, an adhesive (not illustrated) would lie between the substrate structures 606. In another embodiment, the discrete conductive members 620, 720, or combination thereof may be placed between the substrate structures 606, and the first and second substrates may be joined together and sealed at one or more locations not illustrated in FIG. 6 or 7. The remaining portions of the regions between the substrate structures may be evacuated (i.e., under vacuum) or include an inert ambient (e.g., N₂, CO₂, a noble gas, or a combination thereof).

4. Alternative Substrate Structures

FIGS. 9 to 13 illustrate alternative embodiments of substrate structures. These are meant to show examples of the variety of shapes that the substrate structures can have but are not meant to be limiting. FIG. 9 illustrates a pair of joined substrates 600 and 610 similar to those shown in FIG. 7, but with dome-shaped substrate structures 906 that have rounded apexes 908, as opposed to the pointed apexes 608 of the substrate structures 606. In another embodiment, the apexes can be flat. In still another embodiment, any combination of apex shapes can be used.

FIG. 10 illustrates an embodiment including a pair of joined substrates 600 and 610 similar to the ones shown in FIG. 6. However, the substrate structures 606 are replaced with a pair of substrate structures 1006 that are separated by a valley 1010. One or more discrete conductive members 1020 may lie within a valley 1010 and are electrically insulated from the exposed conductor 604 and 614 by substrate structures 1006. Therefore, the discrete conductive members 1020 electrically float. Though shown extending the full height of substrate structures 1006, in one embodiment, the valley 1010 may or may not reach base material 602. In this embodiment, each pair of substrate structures 1006 may contact each other or at least partially merge (e.g. a single substrate structure) to produce an “M” shape.

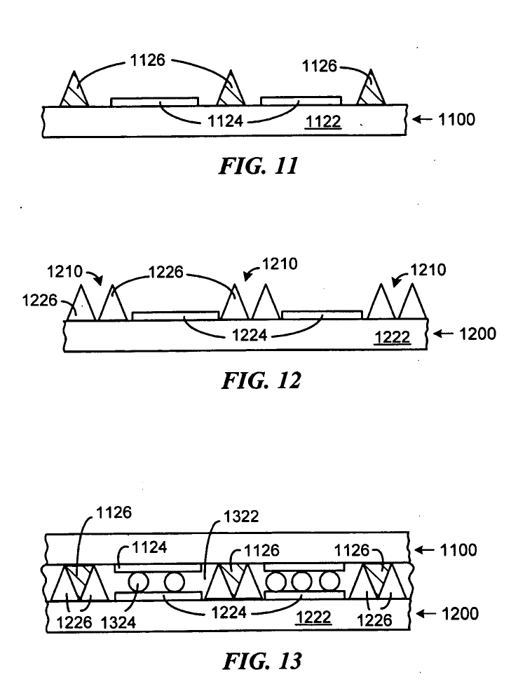

In another embodiment, corresponding structures can be used on each of the substrates being joined. FIG. 11 illustrates a first substrate 1100 comprising a base material 1122, first exposed conductors 1124, and first substrate structures 1126. FIG. 12 illustrates a second substrate 1200 comprising a base material 1222, second exposed conductors 1224 and second substrate structures 1226. Valleys 1210 lie between each pair of the second substrate structures 1226. The valleys 1210 correspond in size, shape and spacing to first substrate structures 1126. Therefore, the first substrate structures 1126 are the complement of the second substrate structures 1226. The first and second substrates 1100 and 1200 are joined using adhesive 1322 and discrete conductive members 1324 that fill the regions between sets of substrate structures 1126 and 1226 to connect the first and second exposed conductors 1124 and 1224 to one another. The substrate structures 1126 are located in the valleys 1210, which helps to align the first and second substrates 1100 and 1200 relative to each other. In another embodiment, adhesive 1322 may lie along the interfaces between the first and second substrate structures 1126 and 1226. The adhesive 1322 may or may not be present in regions between pairs of first and second exposed conductors 1124 and 1224. If the adhesive is not present in regions between pairs of connected exposed conductors 1124 and 1224, such regions, including discrete conductive members 1324, may be evacuated or filled with an inert ambient as previously described.

5. Alternative Process for Joining Substrates

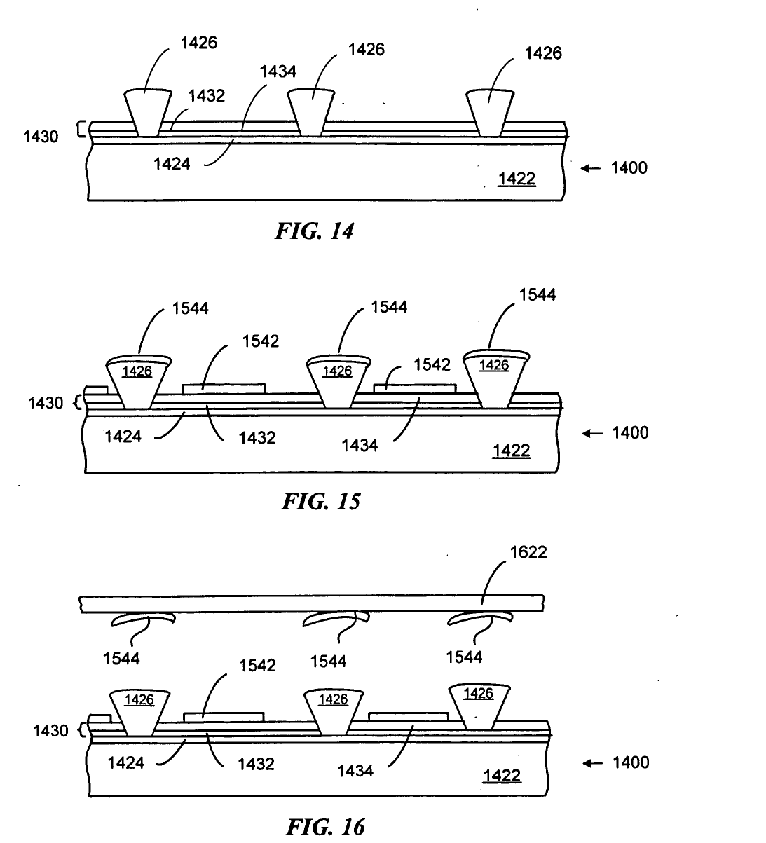

FIGS. 14 to 17 illustrate an alternative process for joining substrates. In one embodiment, a passive matrix display may be formed. FIG. 14 illustrates a substrate 1400 that comprises a base material 1422, first electrodes 1424, which are the anodes for the array, substrate structures 1426, and an organic layer 1430, including an optional charge-transport layer 1432 and an organic active layer 1434, all formed by conventional techniques. Each of the layer(s) within the first electrode 1424, substrate structures 1426, and organic layer 1430 are deposited and may or may not need to be patterned. In one embodiment, base material 1422 and the first electrode 1424 are substantially transparent to the targeted radiation wavelengths or spectrum (spectra) of wavelengths to which the electronic device emits or responds. In another embodiment, more, fewer, or different layer(s) or feature(s) are present. For example, the organic layer may include a charge-injection layer, a charge-blocking layer, or both in place of or in conjunction with the charge-transport layer 1432. In still another embodiment, any one or more of different charge-injection, charge-transport, or charge-blocking layers may lie between the organic active layer 1434 and subsequently formed cathodes.

In one embodiment, the substrate structures 1426 are cathode separators and may or may not receive a surface treatment before forming the organic layer 1430. A conventional fluorination surface treatment may be performed to reduce the surface energy of the substrate structures 1426. The surface treatment may be performed after substrate structures 1426 are formed. In one embodiment, the surface treatment is performed before or after the organic layer 1430 is formed.

Conductive members 1544, which overlie the substrate structures 1426, and exposed conductors 1542, which are second electrodes or cathodes, are formed as illustrated in FIG. 15. In one embodiment, the exposed conductors 1542 are substantially parallel strips extending into and out of the illustration in FIG. 15. The exposed conductors 1542 and A conductive members 1544 are formed using a conventional deposition technique. Conductive members 1544 overlie the substrate structures 1426 and are not connected to the exposed conductors 1542.

An adhesive film 1622 contacts the conductive members 1544 and is pulled away from the substrate 1400 to remove the conductive members 1544, as illustrated in FIG. 16. In one embodiment, care is taken when applying adhesive films 1622 such that it only attaches to conductive members 1544 and not to exposed conductors 1542. Adhesive film 1622 is then removed taking with it conductive members 1544. In one embodiment, care may be taken to remove adhesive film 1622 with conductive members 1544 at a steady rate. Erratic application of force could cause damage to the substrate structures 1426 or leave one or more of conductive members 1544 in place overlaying substrate structures 1426.

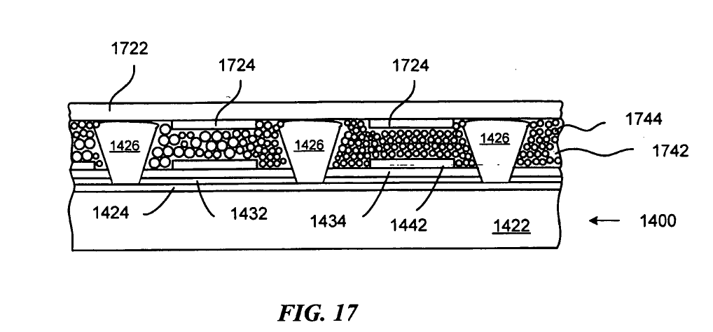

After further processing, a lid 1722, including exposed conductors 1724, is attached to the substrate 1400 to form a substantially completed electronic device as illustrated in FIG. 17. In one embodiment, a bonding layer, comprising an adhesive 1742 and discrete conductive members 1744, is used to attach the lid 1722 to the substrate 1400. The bonding layer substantially fills the volume between the apexes of substrate structures 1426 and above the exposed electrodes 1542. In another embodiment (not illustrated) the discrete conductive members 1744 are used, however, the adhesive 1742 is not used within the array. An adhesive at a rail area outside the array (not illustrated) can be used in accordance with a conventional technique.

The processes described above can form joined substrates that are substantially free of bubbles. However, the absence of bubbles should not be construed as a requirement. An allowance can be made for some bubbles between the substrate, as long as each bubble is not too large. In one embodiment, the diameter of each air bubble is smaller than the pixel size. In another embodiment, the diameter of each air bubble is at least 50% smaller than the shorter dimension (e.g., width) of the pixel as seen from a plan view of the pixel.

6. Advantages

The completed electronic device can be fabricated by assembling two different substrates having different electronic components or conductors. These substrates can be formed and exposed to completely different sets of process conditions. Many processing options become available as electronic components or other structures that are formed over the substrate “first” are no longer exposed to the conditions during the formation of subsequent electronic components or other structures. Such “subsequent” electronic components or other structures are formed separately on a different substrate. The substrates can be tested for functionality separately before joining. In one embodiment, only functional electronic substrates need be combined with functional OLED substrates to form functional devices. If formed by a conventional method using a single substrate, a non-functional OLED may be formed on a functional electronic substrate, effectively creating a non-functional electronic device. Even if this non-functional OLED could be reworked, there is a risk that the extra rework processing will cause the underlying electronic components, circuits, or both to become non-functional or poorly functioning. Further, there is no guarantee that the OLED formed by the rework process would be functional. One of the substrates mentioned could function as a lid in the completed device. Additionally, just the routine processing and handling of the substrates may cause an otherwise working back panel to become non-functional. By joining the two different substrates, the risks from continued processing on single substrates is obviated.

The substrate structures can be used to control the location of the discrete conductive members during either substrate or lid attachment. This decreases the likelihood that an unintended electrical connection will be created during processing. By relying on the substrate structures for electrical insulation, the concentration of discrete conductive members in the bonding layer can be higher than in the prior art, thereby creating a more robust and less resistive electrical connection between the exposed conductors. In another embodiment, the substrate structures provide a fixed spacing between the exposed conductors so that the appropriate size of discrete conductor can be selected to more reliably create contact between the discrete exposed conductors.

Another advantage for at least one embodiment is that complementary substrate structures can be used to aid in position of the substrates relative to each other. Still another advantage for at least one embodiment is that the substrates can be joined substantially bubble free. Bubbles are undesirable in that a small void can be seen as a defect in the finished device. In an extreme case, the bubbles may compromise function of the device. By using the proper materials and carefully controlling the joining operation, including the joining conditions, substantially bubble-free electronic devices can be formed. As previously discussed, note that bubbles can be present and still be within the scope of the present invention.

The displays may be active matrix or passive matrix, and full color or monochrome. Other electronic devices can be formed using part or all of the process, as previously described. A sensor array may be formed instead of a display. The sensor array may be fabricated on one substrate, and other electronics may be formed on another substrate. The two substrates may be joined together as previously described. In still another embodiment, the electronic device may be designed to operate within or outside of the visible light spectrum (e.g., UV or IR).

Note that not all of the activities described above in the general description or the examples are required, that a portion of a specific activity may not be required, and that one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that one or more modifications or one or more other changes can be made without departing from the scope of the invention as set forth in the claims below. Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof have been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

What is claimed is:

1. An electronic device comprising:
a first substrate comprising a first exposed conductor and a second exposed conductor;
a second substrate;
a conductive material including a first portion that contacts the first exposed conductor and a second portion that contacts the second exposed conductor; and
a first substrate structure that electrically insulates the first portion of the conductive material and the first exposed conductor from the second portion of the conductive material and the second exposed conductor.

2. The electronic device of claim 1, wherein from a cross-sectional view, the first substrate structure has an apex that has a point, is rounded, is flat, or a combination thereof.

3. The electronic device of claim 1, further comprising a third exposed conductor, wherein:
the second substrate comprises the third exposed conductor; and
the first portion of the conductive material is connected to the first and third exposed conductors.

4. The electronic device of claim 3, wherein:
discrete conductive members comprise the conductive material; and
the discrete conductive members include a first discrete conductive member and a second discrete conductive member.

5. The electronic device of claim 4, wherein:
the first discrete conductive member contacts the first exposed conductor but not the third exposed conductor; and
the second discrete conductive member contacts the third exposed conductor but not the first exposed conductor.

6. The electronic device of claim 4, wherein the discrete conductive members comprise a third discrete conductive member that electrically floats.

7. The electronic device of claim 6, further comprising a second substrate structure, wherein the third discrete conductive member lies within a valley between the first and second substrate structures.

8. The electronic device of claim 4, wherein the discrete conductive members comprising a conductive organic material, conductive metallic-coated elastic balls, or a combination thereof.

9. The electronic device of claim 3, wherein the conductive material is capable of supporting a current density of at least 1 mA/cm² between the first and third exposed conductors.

10. The electronic device of claim 1, further comprising a second substrate structure, wherein:
the first substrate comprises the first substrate structure;
the second substrate comprises the second substrate structure; and
the first substrate structure and second substrate structure are corresponding structures that can be used for aligning the first and second substrates to each other.

11. A process for forming an electronic device comprising:
depositing a liquid adhesive over a first substrate;
placing the first substrate and a second substrate under vacuum, wherein the second substrate has a first edge and a second edge opposite the first edge;
contacting the liquid adhesive with the second substrate near the first edge of the second substrate;
increasing the contact area between the liquid adhesive and second substrate as the second edge of the second substrate is moved closer to the first substrate; and
curing the liquid adhesive.

12. The process of claim 11, wherein the liquid adhesive has a viscosity no greater than 20 centipoise during increasing the contact area.

13. The process of claim 12, wherein curing comprises exposing the liquid adhesive to radiation or heat, allowing the liquid adhesive to set, or a combination thereof.

14. The process of claim 13, wherein increasing the contact area is performed using an inert ambient.

15. The process of claim 13, wherein the process is performed such that substantially no bubbles are formed between the liquid adhesive and the second substrate.

16. The process of claim 11, further comprising:
forming a substrate structure on the first substrate;
forming a first exposed conductor and a second exposed conductor on the first substrate; and
forming a third exposed conductor and a fourth exposed conductor on the second substrate.

17. The process of claim 16, wherein:
depositing the liquid adhesive comprises depositing a first portion of the conductive material over the first exposed conductor and depositing a second portion of the conductive material over the second exposed conductor; and
the substrate structure lies between the first and second portions of the conductive material.

18. The process of claim 17, wherein:
increasing the contact area comprising contacting the first portion of the conductive material with the third exposed conductor and contacting the second portion of the conductive material with the fourth exposed conductor; and
the substrate structure electrically insulates the first and third exposed conductors from the second and fourth exposed conductors.

19. The process of claim 18, wherein:
forming the first exposed conductor comprises forming a fifth exposed conductor over the substrate structure; and
the process further comprises removing the fifth exposed conductor before depositing the liquid adhesive.

20. An electronic device formed by the process of claim 11.
